(19) United States
(12) Patent Application Publication
(10) Pub. No.: US 2023/0314672 A1
(43) Pub. Date: Oct. 5, 2023

(54) FABRICATION OF OPTICAL ELEMENTS

(71) Applicant: Board of Regents, The University of Texas System, Austin, TX (US)

(72) Inventors: Sidlgata V. Sreenivasan, Austin, TX (US); David Choi, Austin, TX (US); Parth Pandya, Austin, TX (US); Shrawan Singhal, Austin, TX (US)

(21) Appl. No.: 18/008,358

(22) PCT Filed: Jun. 7, 2021
(86) PCT No.: PCT/US2021/036244

§ 371 Date: Dec. 5, 2022

Related U.S. Application Data
(60) Provisional application No. 63/036,087, filed on Jun. 8, 2020.

(51) Int. Cl. G02B 5/18; B82Y 35/00; B82Y 40/00

(52) U.S. Cl. CPC G02B 5/1857; B82Y 35/00; B82Y 40/00; G06F 3/011

(57) ABSTRACT

A method for introducing a customized variation of a geometric parameter in a nanoscale pattern on a substrate. A nanoscale precision programmable profiling process is conducted on one or more regions of the substrate with the nanoscale pattern, where the nanoscale precision programmable profiling process is used to deposit a profiling film with a thickness profile that is a function of the customized variation of the geometric parameter in the nanoscale pattern. The method further comprises conducting a plasma etch process of the profiling film and the material of the nanoscale pattern that converts the thickness profile of the profiling film into the customized variation of the geometric parameter in the nanoscale pattern, where the customized variation is a function of the thickness profile of the profiling film.

### TECHNICAL FIELD

The present invention relates generally to optical fabrication, and more particularly to fabricating optical elements on a substrate using the nanoscale precision programmable profiling process.

### BACKGROUND

Optical fabrication involves the fabrication of optical components, such as lenses, prisms, mirrors, microlenses, gradient-index lenses, diffractive optics and waveguides. When optical components, such as lenses, prisms and mirrors, are fabricating in optical workshops, various processes, such as cutting, grinding, lapping and polishing may be applied for finally producing optical surfaces with high quality.

However, for more specialized optical components, such as microlenses, gradient-index lenses, diffractive optics and waveguides, a more complex fabrication technique is utilized. Examples of such complex fabrication techniques include magnetorheological finishing, polishing using deformable tools, computer-controlled polishing, etc.

Unfortunately, the processing accuracy is low in such currently used optical fabrication techniques. For example, in a conventional optical fabricating method utilizing ultraviolet irradiation, light is absorbed not only at a light focused point but also in portions irradiated with light and a curing reaction occurs therein. As a result, processing accuracy is low.

### SUMMARY

In one embodiment of the present invention, a method for introducing a customized variation of a geometric parameter in a nanoscale pattern on a substrate comprises conducting a nanoscale precision programmable profiling process on one or more regions of the substrate with the nanoscale pattern, where the nanoscale precision programmable profiling process is used to deposit a profiling film with a thickness profile that is a function of the customized variation of the geometric parameter in the nanoscale pattern. The method further comprises conducting a plasma etch process of the profiling film and material of the nanoscale pattern that converts the thickness profile of the profiling film into the customized variation of the geometric parameter in the nanoscale pattern, where the customized variation is a function of the thickness profile of the profiling film.

In another embodiment of the present invention, a method for correcting one or more aberrations in a waveguide substrate comprises performing a nanoscale precision programmable profiling process on an unpatterned portion of the waveguide substrate by depositing a profiling film on the unpatterned portion of the waveguide substrate with a customized variation to correct for the one or more aberrations in the waveguide substrate.

Furthermore, in one embodiment of the present invention, an apparatus for introducing a customized variation of a geometric parameter in a nanoscale pattern on a substrate comprises a profiling module, where the profiling module has an inkjet for depositing a profiling film on a substrate with a thickness profile that is a function of the customized variation of the geometric parameter in the nanoscale pattern on the substrate, where a plasma etch process is conducted on the profiling film and material of the nanoscale pattern that converts the thickness profile of the profiling film into the customized variation of the geometric parameter in the nanoscale pattern on the substrate, and where the customized variation is a function of the thickness profile of the profiling film.

Additionally, in one embodiment of the present invention, an XR device comprises a waveguide that is fabricated using nanoscale precision programmable profiling for one or more of the following: introducing a customized variation in a geometric parameter of a nanoscale pattern on the waveguide, correction of substrate flatness or total thickness variation errors, and correction of image distortions or optical aberrations.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 is a schematic view of the nP3 apparatus in accordance with an embodiment of the present invention;

FIG. 2 is a schematic view of the profiling subsystem in the nP3 apparatus in accordance with an embodiment of the present invention;

FIG. 3 is a flowchart of a method for fabricating elements on flat substrates using the nanoscale precision programmable profiling (nP3) process in accordance with an embodiment of the present invention;

FIGS. 4A-4H depict cross-sectional views for fabricating elements on flat substrates using the steps described in FIG. 1 in accordance with an embodiment of the present invention;

FIG. 5 is a flowchart of a method for fabricating optical elements on flat substrates using the nanoscale precision programmable profiling (nP3) process with a superstrate in accordance with an embodiment of the present invention;

FIGS. 6A-6H depict cross-sectional views for fabricating optical elements on flat substrates using the nP3 process with a superstrate using the steps described in FIG. 5 in accordance with an embodiment of the present invention;

FIG. 7 depicts a waveguide substrate showing nanoscale pattern regions as the incoupling diffractive optical element (DOE) and the outcoupling DOE in accordance with an embodiment of the present invention;

FIG. 8 depicts a waveguide substrate showing nanoscale pattern regions as the incoupling DOE and the outcoupling DOE in which the nanoscale pattern regions have been shown with a customized variation in their geometric parameters in accordance with an embodiment of the present invention;

FIG. 9 illustrates having multiple nanoscale pattern regions on the same substrate in accordance with an embodiment of the present invention;

FIG. 10 illustrates using the nP3 process on an unpatterned portion of the waveguide substrate to correct for aberrations in accordance with an embodiment of the present invention;

FIG. 11 illustrates a method for introducing a customized variation in a geometric parameter of a nanoscale pattern using substantially similar etch rates for the profiling and nanoscale pattern materials in accordance with an embodiment of the present invention;

FIGS. 12A-12D depict cross-sectional views for introducing a customized variation in a geometric parameter of a nanoscale pattern using the steps described in FIG. 11 in accordance with an embodiment of the present invention;

FIG. 13 illustrates a method for introducing a customized variation in a geometric parameter of a nanoscale pattern using dissimilar etch rates for the profiling and nanoscale pattern materials in accordance with an embodiment of the present invention; and

FIGS. 14A-14D depict cross-sectional views for introducing a customized variation in a geometric parameter of a nanoscale pattern using the steps described in FIG. 13 in accordance with an embodiment of the present invention.

### DETAILED DESCRIPTION

As stated in the Background section, the processing accuracy in currently used optical fabrication techniques is low. For example, in a conventional optical fabricating method utilizing ultraviolet irradiation, light is absorbed not only at a light focused point but also in portions irradiated with light and a curing reaction occurs therein. As a result, processing accuracy is low.

The principles of the present invention provide a means for improving the processing accuracy in fabricating optical elements by utilizing a process referred to herein as the “nanoscale precision programmable profiling (nP3).” The nP3 process may be used in the context of fabricating optical elements, such as waveguides for augmented and mixed reality applications, diffractive optical elements with one or more varying geometric properties (e.g., depth), etc. In one embodiment, such diffractive optical elements are part of a waveguide and can be used for in-coupling light from a projector, pupil expansion or out-coupling to the eye. In general, the nP3 process can be applied to introduce a desired customized variation in a geometric parameter of an existing nanoscale pattern. A discussion regarding the nP3 process is discussed in International Application No. PCT/US14/51526 entitled “Programmable Deposition of Thin Films of a User-Defined Profile with Nanometer Scale Accuracy,” filed on Aug. 18, 2014 and in International Application No. PCT/US21/19732 entitled “Nanoscale Thin Film Deposition Systems,” filed on Feb. 25, 2021, which are both incorporated by reference herein in their entirety.

In one embodiment of the process, a nanoscale precision programmable profiling (nP3) process is carried out on flat substrates. These flat substrates may include one or more regions with a nanoscale pattern, where such a nanoscale pattern may be similar or substantially different from one region to another. In one embodiment, the flat substrates represent waveguide substrates used for virtual, augmented or mixed reality (collectively, XR) applications. In one embodiment, the regions with nanoscale patterns represent diffractive optical elements that are used for waveguide light coupling purposes, where the diffractive optical elements may be used for incoupling light from a projector, pupil expansion, or outcoupling light to the eye. The nP3 process allows a profiling film to be deposited on one or more regions with the nanoscale pattern, such that the profiling film has a desired customized thickness variation. In one embodiment, the profiling film has an optical property that is substantially matched with the nanoscale pattern. In one embodiment, the profiling material is a UV-curable polymer resist (e.g., mrUVcur26SF from Microresist Technologies). This thickness variation is a function of a desired customized variation in one or more geometric parameters of the nanoscale pattern, where such geometric parameters include, but are not limited to, a height of a feature in the pattern, a width of a feature in the pattern, and an angle of a feature in the pattern. The desired customized variation in a geometric parameter can be different across different regions of the substrate with the nanoscale pattern. For example, a first region may require a different height profile compared to a second region, whereas, a third region may have the same variation as the first region but with a different orientation. The purpose of such customized variations in one or more geometric parameters of the nanoscale pattern is to render desirable functional or optical properties to the waveguide. In one embodiment, this property includes maintaining a substantially uniform coupling intensity across the outcoupling or pupil expansion optical elements. Furthermore, in one embodiment, the nanoscale pattern exists on the substrate, whereas, in another embodiment, the nanoscale pattern is formed on another material on the substrate, such as a functional film (e.g., a high-refractive index polymer material, such as material #18165 from Nippon Telegraph and Telephone-Advanced Technology). As used herein, the nanoscale pattern material refers to either the substrate or the above different material on the substrate used to form the nanoscale pattern. The thickness profile is then transferred to the nanoscale pattern material via a plasma etch process such that a desired customized variation in one or more geometric parameters in the nanoscale pattern on the substrate is introduced. In one embodiment, multiple iterations of either the profiling or plasma etch steps are used to introduce the customized variation. An embodiment of the nP3 process on flat substrates is described below.

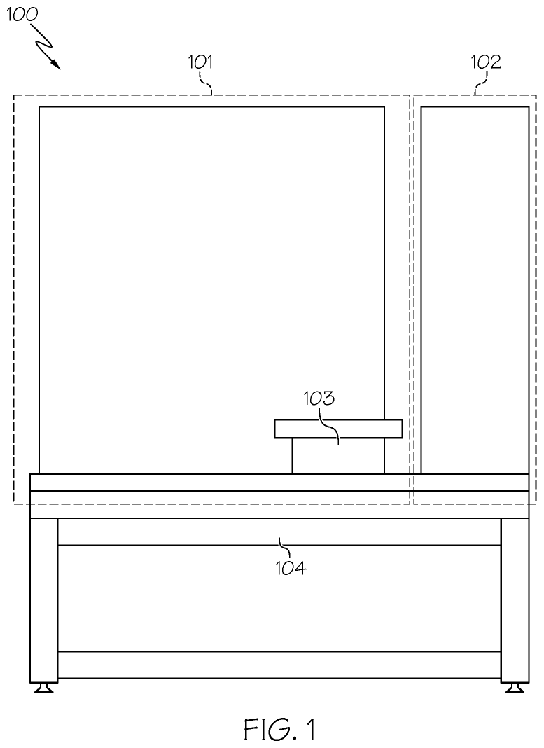

Referring now to the Figures in detail, FIG. 1 is a schematic view of the nP3 apparatus 100 in accordance with an embodiment of the present invention.

The nP3 apparatus 100 consists of 2 main subsystems: profiling 101 and metrology 102. The profiling subsystems includes a web handling module consisting of unwind and rewind rollers, rollers for interleaving and de-interleaving, drive rollers, nip rollers for tension control and precision rollers to ensure a flat zone. The sidelay ensures that web is wound on each other without lateral error (telescoping). An inkjet printhead on an alignment stage dispenses profiling material drops. The UV lamp and UV transparent (UVT) chuck are used to cure the profiling material and hold the superstrate in place while creating an air-pressure induced curvature to spread the profiling material drops. The voice coil motor driven flexure bearing stage holds the substrate chuck below the superstrate and is mounted on linear horizontal stages 103 as shown. The metrology subsystem includes a sensor for surface topography measurement (a Shack-Hartman sensor, an optical profilometer, an interferometer, an optical profilometer, a reflectometer or a spectrophotometer) mounted directly above the substrate. A laser beam is guided to transmit through the substrate through an automated telescopic system and is incident on the sensor. A telescopic system is necessary when dealing with curved substrates with a range of spherical powers. The laser beam alignment system includes a turn mirror which directs a horizontal laser beam vertical upwards through the substrate. In one embodiment, the nP3 apparatus 100 also has a communication module with allows transfer and exchange of data locally with another computer or with another data center/workstation located remotely (e.g., cloud-based datacenter, cloud-based workstation). This data can include metrology data, tool sensor data, drop pattern data, etc.

Referring again to FIG. 1, nP3 apparatus 100 further includes a granite base and support table 104.

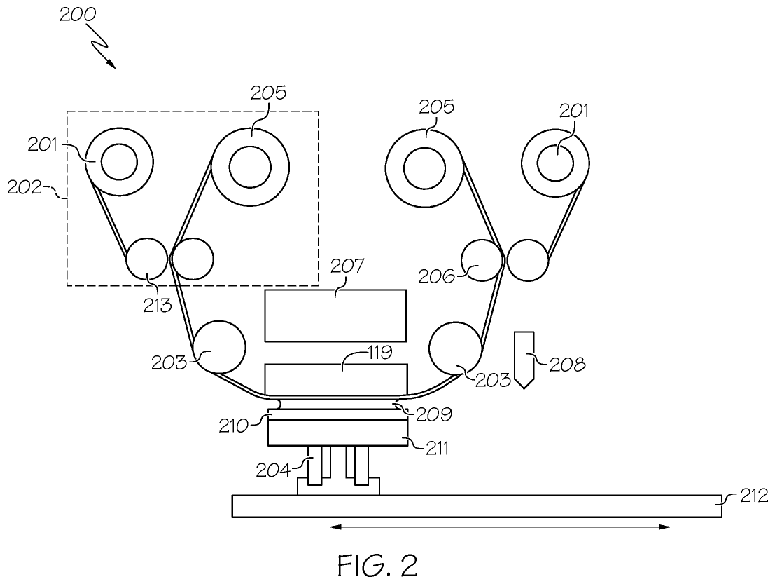

Referring now to FIG. 2, FIG. 2 is a schematic view of the profiling subsystem 200 in nP3 apparatus 100 in accordance with an embodiment of the present invention.

As shown in FIG. 2, profiling subsystem 200 includes a motorized interleaf/de-interleaf rollers 201, nip roller 213, sidelay module 202, precision idlers 203, UV transparent vacuum chuck 119, voice coil motor (VCM) driven stage 204 for vertical, tip and tilt motion, motorized supply and take-up rollers 205, drive roller 206, curing module 207, stationary inkjet printhead 208, profiling material 209, rigid substrate 210, vacuum pin chuck 211 and large travel stage 212. In one embodiment, rigid substrate 210 is either nominally flat or nominally non-flat (e.g., spheres, aspheres). A “rigid” substrate, as used herein, refers to having permanent shape and form. “Nominally flat,” as used herein, refers to a surface having an area of apparent contact being so large so that the individual contacts are dispersed and the forces acting through neighboring spots do not influence each other. “Nominally non-flat,” as used herein, refers to a surface that is not nominally flat.

As illustrated in FIG. 2, inkjet printhead 208 is stationary with respect to the large travel direction 212.

Furthermore, FIG. 2 shows the web path followed by the superstrate and the interleaf film during removal and reapplication. In FIG. 2, tension control is achieved through a nip and drive roller assembly (see 213 and 206). In one embodiment, polyurethane rollers are used to apply normal pressure on drive roller 206 which improves friction and allows higher tension limited by motor capacity. In one embodiment, it is ensured that nip roller 213 is axially parallel to drive roller 206. A UV lamp is placed directly above the profiling zone. UV transparent chuck 119 is positioned between the superstrate and the UV lamp. Precision idlers 203 are shown which flatten the superstrate and ensure minimal out of plane errors and in plane shear errors. The voice coil motor stage 204 is mounted to a horizontal XY stage. The substrate is traversed from the jetting station to the profiling station and then to the metrology station using the XY stages.

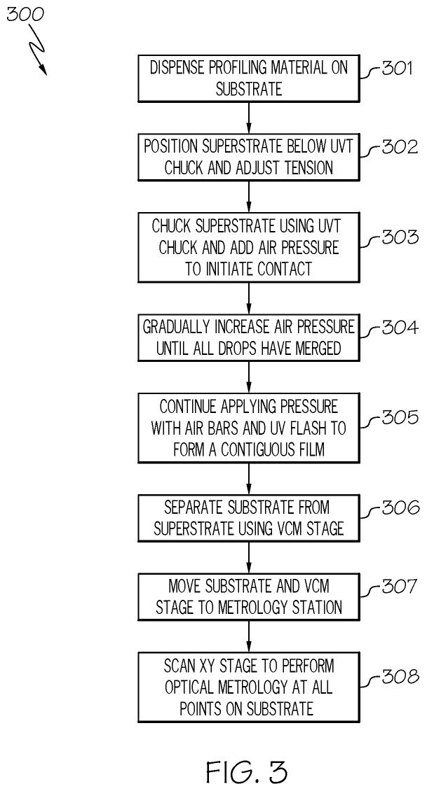

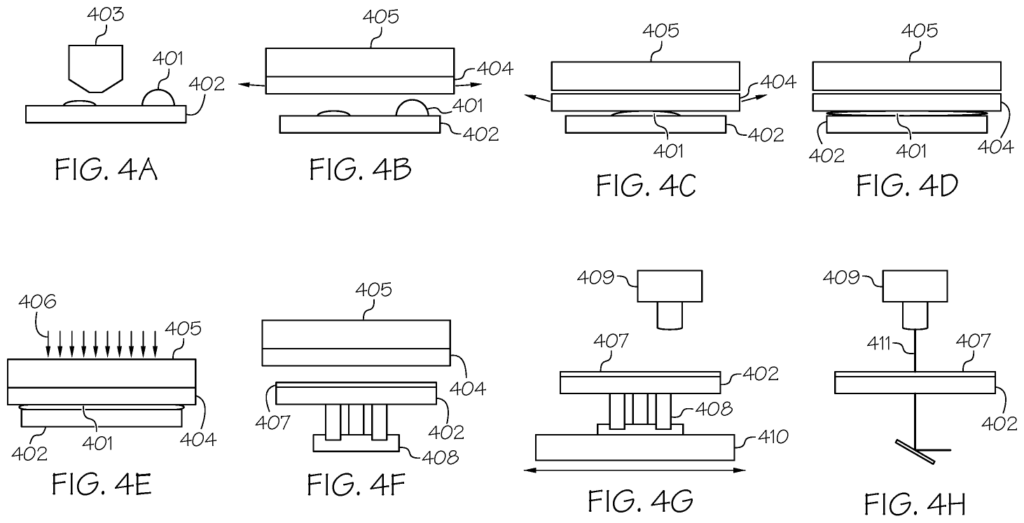

FIG. 3 is a flowchart of a method 300 for fabricating elements on flat substrates using the nanoscale precision programmable profiling (nP3) process in accordance with an embodiment of the present invention. FIGS. 4A-4H depict cross-sectional views for fabricating elements on flat substrates using the steps described in FIG. 3 in accordance with an embodiment of the present invention.

Referring to FIG. 3, in conjunction with FIGS. 4A-4H, in step 301, profiling material 401 is dispensed on a substrate 402 using an inkjet 403 as shown in FIG. 4A. In one embodiment, profiling material dispensing locations are determined using an algorithm run in one of the following locations: a local computer, a remote computer, and a cloud-based computer.

In step 302, superstrate 404 is positioned below ultraviolet transparent (UVT) chuck 405 and the tension is adjusted as shown in FIG. 4B.

In step 303, superstrate 404 is chucked using UVT chuck 405 as shown in FIG. 4C. Furthermore, in step 303, air pressure is added to initiate contact (contact between superstrate 404 and substrate 402) as shown in FIG. 4C.

In step 304, air pressure is gradually increased until all drops have merged as shown in FIG. 4D.

In step 305, pressure with air bars is continually applied with UV (ultraviolet) flash 406 to form a contiguous film 407 as shown in FIGS. 4E and 4F.

In step 306, substrate 402 is separated from superstrate 404 using vertical chuck motion (VCM) stage 408 as shown in FIG. 4F.

In step 307, substrate 402 and VCM stage 408 are moved to metrology station 409 using x stage 410 as shown in FIG. 4G.

In step 308, xy stage is scanned to perform optical metrology at all points on substrate 402 via laser beam 411 (corresponding to final substrate profile) as shown in FIG. 4H.

A more detailed description of method 300 in connection with FIGS. 4A-4H is provided below.

Referring to FIGS. 3 and 4A-4H, during the process of fabricating optical elements on flat substrates 402 using nP3, a drop pattern 401 is generated and dispensed on flat substrate 402 over a large area. In one embodiment, substrate 402 may have existing nanoscale features or patterns, where such nanoscale features may correspond to optical elements or diffractive optical elements as they can interact with electromagnetic radiation to cause diffraction effects. The inkjetted drops or drop pattern 401 is generated to account for spreading, merging and filling in the presence of existing features on substrate 402 and a desired film thickness profile based on a customized spatial variation in one or more geometric parameters in the features. This is achieved through XY motion of substrate 402 synchronized with jetting cycles. In one embodiment, substrate 402 is then traversed to the profiling zone underneath an ultraviolet (UV) lamp and UV Transparent (UVT) chuck 405.

In one embodiment, superstrate 404 is positioned below UVT chuck 405 and the tension in superstrate 404 is adjusted to the desired level as necessitated by the final surface profile. Superstrate 404 can be a textured or patterned roll, where the lateral spatial length scale of the texture or pattern is at least an order of magnitude lower than the lateral spatial length scale of the desired profile. In one embodiment, UVT chuck 405 is used to then hold superstrate 404 in place. The voice coil motor driven stage with substrate 402 mounted on a chuck is brought to the profiling zone with the help of horizontal XY stages. The vertical tip tilt motion of the Vertical Chuck Motion (VCM) stage 408 allows proper alignment of substrate 402 with superstrate 404 and gap control. Air pressure is increased in the cavity to create a curvature of the superstrate web which allows the drops to merge and form a contiguous film 407. This allows mitigation of any entrapped air bubbles. In one embodiment, cameras mounted on the UVT chuck 405 are used to observe bubble entrapment. Using image processing, bubbles are identified and air is automatically pumped on superstrate 404 at targeted locations to ensure drops of profiling material 401 there spread and the bubbles are mitigated. After a specified amount of time necessary for capillary forces to create the desired topography, the profiling material is UV cured. In one embodiment, VCM stage 408 is used to separate substrate 402 from superstrate 404 through its vertical motion.

In one embodiment, substrate 402, along with the VCM stage 408, are brought to metrology station 409. In one embodiment, VCM stage 408 helps align substrate 402 face at the point of measurement with the optical axis of the optical metrology instrument, such as a profilometer, a Shack-Hartmann wavefront sensor, an interferometer, a reflectometer, etc. In one embodiment, machine instructions (e.g., drop pattern) for obtaining the desired thickness profile are determined using an automated algorithm.

For the nP3 process, instead of using inkjets for a programmable film, an alternative embodiment involves the use of a substantially uniform profiling film that is deposited on the substrate using techniques, such as spin-coating, slot-die coating, dip coating, etc. The uniform film is thick enough to fill the existing features on the substrate as well as to substantially match the highest thickness that needs to be present after the customized profile is obtained. In this case, a customized profile is obtained by differential heating of the profiling film using devices, such as one or more spatial light modulators (e.g., digital micromirror device (DMD) arrays) connected to lamps that emit radiation at the desired wavelengths (e.g., 3.3 micrometers) where the profiling material (e.g., methyl methacrylate) or the substrate absorbs, an array of microheaters on the substrate chuck, etc. In one embodiment, differential heating can cause flow in the coated film through one or more of the following mechanisms: thermal gradients, Marangoni flow due to surface tension gradients, evaporation, or composition gradients. In one embodiment, a model of the flow of the film can be used to determine the spatial and temporal differential heating characteristics, such that a flow transient gives the desired film thickness profile. The film is then cross-linked to “freeze” the transient state. This alternative embodiment can be used with or without a superstrate based on the need to control evaporation or to add an additional control knob to the flow of the coated film.

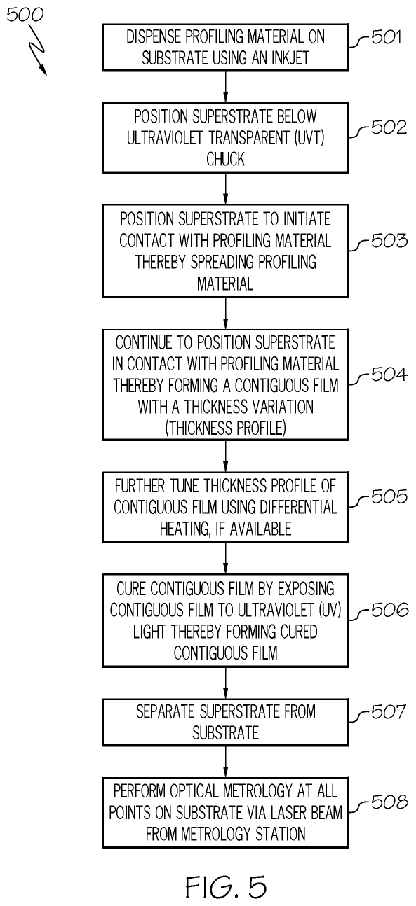

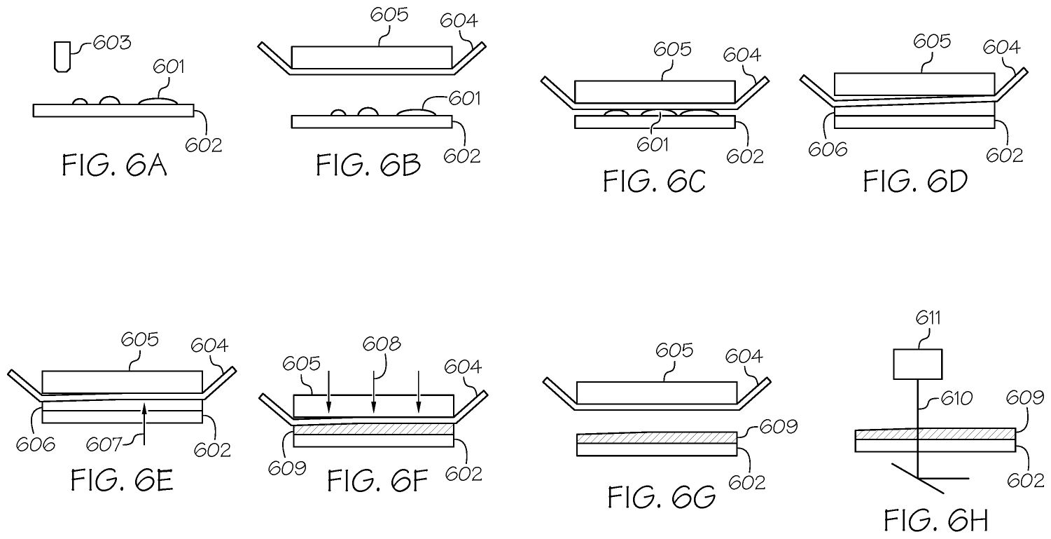

FIG. 5 is a flowchart of a method 500 for fabricating optical elements on flat substrates using the nanoscale precision programmable profiling (nP3) process with a superstrate in accordance with an embodiment of the present invention. FIGS. 6A-6H depict cross-sectional views for fabricating optical elements on flat substrates using the nP3 process with a superstrate using the steps described in FIG. 5 in accordance with an embodiment of the present invention.

Referring to FIG. 5, in conjunction with FIGS. 6A-6H, in step 501, profiling material 601 is dispensed on a substrate 602 using an inkjet 603 as shown in FIG. 6A. In one embodiment, profiling material dispensing locations are determined using an algorithm run in one of the following locations: a local computer, a remote computer, and a cloud-based computer.

In step 502, superstrate 604 is positioned below ultraviolet transparent (UVT) chuck 605 as shown in FIG. 6B.

In step 503, superstrate 604 initiates contact with profiling material 601 thereby spreading profiling material 601 as shown in FIG. 6C.

In step 504, superstrate 604 continues to be in contact with profiling material 601 thereby forming a contiguous film 606 with a thickness variation (thickness profile) as shown in FIG. 6D.

In optional step 505, the thickness profile of contiguous film 606 is further tuned using differential heating 607, if available, as shown in FIG. 6E.

In step 506, contiguous film 606 is cured by exposing contiguous film 606 to ultraviolet (UV) light 608 thereby forming cured contiguous film 609 as shown in FIG. 6F.

In step 507, superstrate 604 is separated from substrate 602 as shown in FIG. 6G.

In step 508, optical metrology is performed at all points on substrate 602 via laser beam 610 from metrology station 611 as shown in FIG. 6H.

In an alternative embodiment, optical elements may be fabricated on flat substrates using the nP3 process without the use of a superstrate by simply performing steps 501 and 505-508 as discussed above. In such an embodiment, after dispensing the profiling material on the substrate, the thickness profile of the profiling material is tuned using differential heating.

In one embodiment, the nP3 process can be utilized for application in precision optics as discussed below.

Precision optical elements include mirrors and lenses for a wide variety of applications. Depending on the application, such elements may need to be fabricated from different substrate materials, and can either be flat, freeform or nominally curved. The nP3 process can be used to either correct the existing topography on a substrate to match a desired topography, or can be used to generate an entirely different profile from a starting substrate. In some applications, the nP3 process deposits a functional film which is left behind on the substrate. For example, for optical applications, the functional material may be a film with a refractive index which is matched with that of the substrate. For example, a high-index polymer resist (e.g., #18165 from Nippon Telegraph and Telephone-Advanced Technology) may be used on a high-index waveguide substrate (e.g., Schott Realview). In one embodiment, the nP3 process is executed on the patterned side of het high-index waveguide substrate. For some applications, the nP3 process deposits a sacrificial film (e.g., mrUVcur26SF from Microresist Technologies) which can then be used to transfer the profile of the film into the substrate or the underlying nanoscale pattern material using an etching step. These applications include those where the presence of a polymer film can degrade the functionality of the substrate and thus needs to be removed, for example, for high intensity laser beam optics. The etching step is usually conducted in a plasma chamber to get the desired match between the etch rate of the sacrificial profiling material and the underlying nanoscale pattern material. The etch gases used can be a combination of O₂, inert gases (e.g., Ar), fluorinated gases (CHF₃, CF₄, SF₆, etc.) or other halogen gases (Cl₂, HBr, etc.). In one embodiment, the ratio of the etch rates of the profiling film and the nanoscale pattern material is substantially matched. In one embodiment, the profiling film has an optical property that is substantially matched with the nanoscale pattern, where such an optical property includes a refractive index at one or more wavelengths. In one embodiment, the desired match between the etch rates can be tuned to be a ratio between 0.05:1 and 20:1. This tuning is obtained by adjusting the relative flow rates between the physical (O₂, inert gases) and chemical (fluorinated chemistries, other halogens) etch constituents. For example, increasing the flow rates of O₂ and Ar increases the etch rate of the polymer material, while keeping the etch rate of a material, such as fused silica, substantially unaffected. In one embodiment, the etch rate of the polymer resist is between 10-1000 nm/min. In one embodiment, the etching step itself can be broken down into multiple coarse and fine iterations, where a substantial amount of material can be removed in the coarse steps with high etch rates for high throughput, with the fine steps correcting the errors in the desired profile. Intermediate metrology can be conducted between the coarse and fine steps. Furthermore, in some applications, an additional uniform film may be deposited on the nP3 profiling film. For example, a uniform metal layer may be deposited after the nP3 process such that it can render optical reflective properties with the appropriate profile to a substrate. Some exemplar applications of the nP3 process towards precision optical surfaces are described below.

Augmented Reality (AR)/Mixed Reality (MR), collectively “XR,” headsets require the use of high-refractive index waveguides that propagate light from a display to a pupil near the eye. This virtual image is superimposed on the real world perceived by the eye. These waveguides typically have gratings that couple at least one wavelength of the light incident on the gratings from a microdisplay into the waveguides at an angle that allows the light to undergo total internal reflection into the waveguide. The light is then coupled out of the waveguide with the help of one or more gratings. These waveguides are fabricated from substrates that need to have good flatness and/or total thickness variation (TTV). This is because substantial deviations from a flat waveguide with near zero TTV will either shift the light beam from the desired path or cause the beam to change its diameter, thereby distorting the virtual image with respect to the real image. Moreover, these headsets may have multiple waveguides, with each waveguide addressing one or more wavelengths. Hence, if each waveguide causes its beam to shift differently from another waveguide in the same headset, the combined image can lead to chromatic aberrations.

The higher the number of reflections in a waveguide, the higher the distortion in the image at the exit pupil of the waveguide. The number of reflections is increased by increasing the distance between the incoupling gratings and the outcoupling gratings or the exit pupil. Hence, rays of light that travel further into the waveguide suffer from higher deviation than desired, if the waveguide is imperfect. The number of reflections is also increased when the substrate thickness is reduced to lower the weight of the waveguide and thereby the headset itself.

The nP3 process for flat substrates of the present invention can be used to correct the flatness and TTV in transparent waveguide substrates by depositing a film that corrects the inherent TTV and/or flatness error in the substrate. In one embodiment, the starting substrate can be of lower quality which does not meet the flatness/TTV specs. In one embodiment, the starting substrate can be a substrate with thickness lower than currently available (for example, 100 micrometers). In one embodiment, the starting substrate has specifications that meet the desired specifications and obtain a substantial improvement after the nP3 process. Since the waveguide substrates typically have a refractive index of 1.6 and higher, a sacrificial film may be used for depositing the profile and then transferring the same to the substrate. Alternatively, high index profiling materials, such as high index profiling materials developed by Microresist® and Nippon Telegraph and Telephone-Advanced Technology, may also be used as a functional film that is left behind if the index closely matches that of the substrate, and if spurious reflections off the interface do not lead to a substantial loss in light intensity. In one embodiment, flatness/TTV correction can be combined with texturing of a moth-eye structure for anti-reflective properties. In one embodiment, both sides of a substrate are profiled, and may also have texturing.

In addition to the above, the nP3 process can also be used to correct TTV/flatness errors in the finished waveguide by profiling an unpatterned portion of the waveguide substrate. These errors can be a result of inherent TTV/flatness errors in the starting substrate or prior fabrication steps. For example, nanoimprint lithography leaves a residual layer, and any non-uniformity in the residual layer can add to flatness/TTV errors. Also, deposition of films, such as anti-reflective coatings, can also have their inherent non-uniformities and thereby contribute to flatness/TTV errors. Furthermore, anticipated variations in the TTV/flatness from subsequent steps, such as packaging, can also lead to additional TTV/flatness errors. The profile can be calculated based on measurements of actual aberrations or models that predict the dependence of image translation, magnification and other distortions and aberrations on deviations from TTV/flatness in the finished waveguide, based on measurements performed on the same finished waveguide. This unpatterned portion can be an entire surface which is devoid of any nanoscale features that make the diffractive optical element. In one embodiment, the unpatterned portion of the substrate (e.g., waveguide substrate) has a nanoscale texture. Moreover, the profiling material can be left behind on the substrate if the refractive index of the profiling film is substantially matched with the index of the substrate at the wavelengths of interest. If the index is not matched, nanotextured moth-eye structures can be used to reduce parasitic reflection off the interface.

XR waveguide substrates use diffractive optical elements for several purposes. An incoupling diffractive optical element is used to couple light into the waveguide from a projector. This diffractive optical element can be a diffraction grating (e.g., a binary grating, a phase grating, a surface relief grating, a Bragg grating, a one-dimension (1D) grating, a two-dimension (2D) grating, slanted gratings, multilevel gratings, or some combinations thereof, etc.), a volume hologram, or a photonic crystal. This coupled light is then totally internally reflected through the waveguide substrate. During the total internal reflection, the light may be subject to additional diffractive optical elements in its path. These diffractive optical elements can also be a diffraction grating (e.g., a binary grating, a phase grating, a surface relief grating, a Bragg grating, a 1D grating, a 2D grating, multi-level gratings or some combinations thereof, etc.), a volume hologram, or a photonic crystal. The purpose of these elements is to expand the image in at least one dimension, preferably in both dimensions and to allow the light to be exited to the eye, and to allow the image to be seen at different locations from within what is called an eye box. The expanded and outcoupled light should not suffer from significant distortions in the quality of the image when compared against the quality of the image incoupled into the waveguide from the projector. Several factors determine the quality of the image. The diffractive optical elements cause light to be diffracted in many orders, with the primary order having the highest intensity, and which is primarily utilized for imaging. However, several other orders of lower intensity may also exist and cause losses in intensity each time the light interacts with a diffractive optical element. Also, diffraction characteristics and diffraction efficiencies are different for different wavelengths, implying that light of different wavelengths will diffract at different angles.

Moreover, due to fabrication errors leading to undesirable deviations in the diffractive optical element (DOE) geometry from the designed geometry, the wavelength of light diffracted in the primary order may shift or have undesirable variations in intensities. For example, it is known that the grating height or depth controls the intensity of light which is diffracted However, as a portion of the light is outcoupled from one area, the remaining portion continues to propagate inside the waveguide, and is outcoupled from other portions of the waveguide. If the grating depth is uniform everywhere, the intensity of the light outcoupled from a beginning portion of the waveguide, where the incident intensity is maximum, will be exponentially higher than the intensity of the light outcoupled from an ending portion of the waveguide, where the incident intensity is exponentially lower because a significant portion of the light has been outcoupled in prior portions of the waveguide. Hence, in order to obtain a uniform intensity of light across the eye box which has multiple pupils, it is desirable to have a non-uniform grating height, such that the grating efficiency or the fraction of light which is outcoupled varies progressively from being low in a beginning portion of the waveguide and high in an ending portion of the waveguide. In one embodiment, in order to achieve a color image in the eye, three different designs of the DOEs are needed for the three primary color wavelength bands, such that they can be combined to provide the necessary image. It is noted that any dispersion in the color spectrum because of the aforementioned factors would cause undesirable chromatic aberrations in the image.

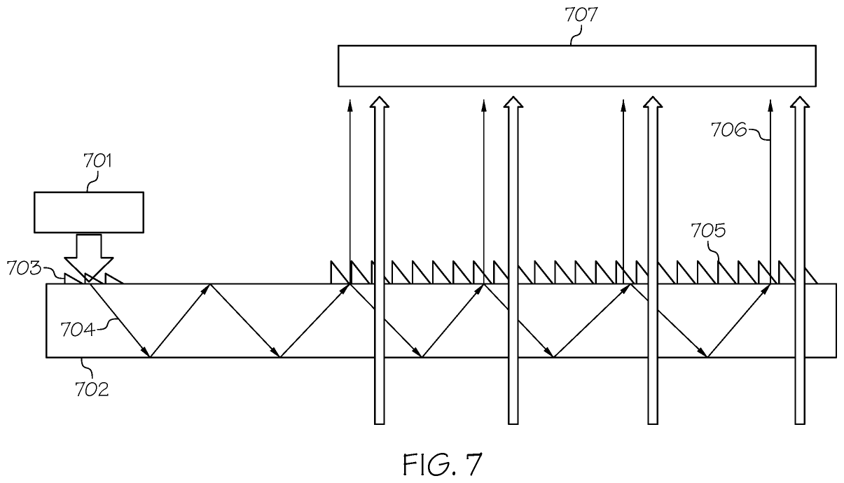

Referring now to FIG. 7, FIG. 7 depicts a waveguide substrate showing nanoscale pattern regions as the incoupling DOE and the outcoupling DOE in accordance with an embodiment of the present invention.

As shown in FIG. 7, a projector 701 injects a virtual image into a waveguide 702 in which the incoupling DOE 703 couples light 704 into waveguide 702. The real image is then transmitted through waveguide 702.

As further shown in FIG. 7, the outcoupling DOE 705 couples light 706 out of waveguide 702 in eye box 707.

Furthermore, as shown in FIG. 7, a real image 708 is transmitted through waveguide 702.

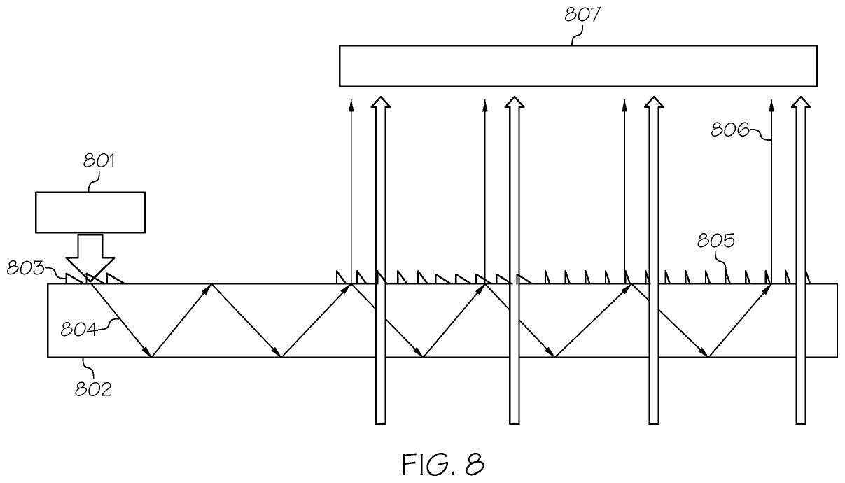

Referring now to FIG. 8, FIG. 8 depicts a waveguide substrate showing nanoscale pattern regions as the incoupling DOE and the outcoupling DOE in which the nanoscale pattern regions have been shown with a customized variation in their geometric parameters in accordance with an embodiment of the present invention.

As shown in FIG. 8, a projector 801 injects a virtual image into a waveguide 802 in which the incoupling DOE 803 (with a customized variation in its geometric parameters) couples light 804 into waveguide 802. The real image is then transmitted through waveguide 802.

As further shown in FIG. 8, the outcoupling DOE 805 (with a customized variation in its geometric parameters) couples light 806 out of waveguide 802 in eye box 807.

Furthermore, as shown in FIG. 8, a real image 808 is transmitted through waveguide 802.

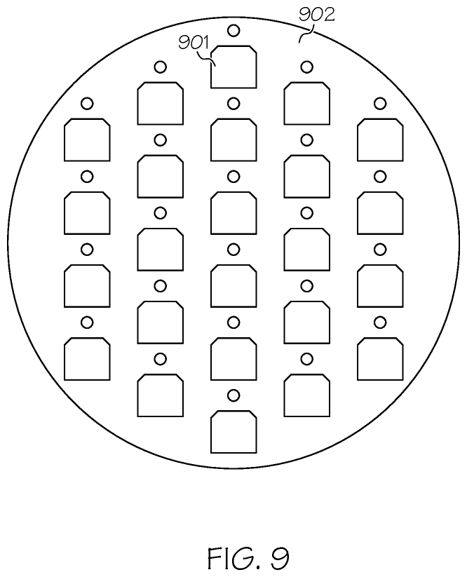

As previously discussed, FIGS. 7 and 8 depict a waveguide substrate showing nanoscale pattern regions as the incoupling DOE and the outcoupling DOE in accordance with an embodiment of the present invention. As also previously discussed, the substrates discussed herein may include one or more regions with a nanoscale pattern, where such a nanoscale pattern may be similar or substantially different from one region to another. For example, as shown in FIG. 9, FIG. 9 illustrates having multiple nanoscale pattern regions 901 on the same substrate 902 in accordance with an embodiment of the present invention.

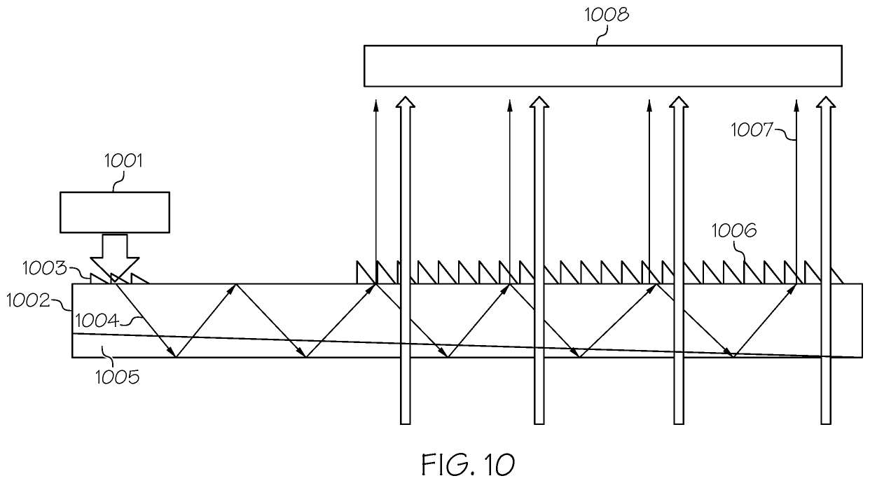

Furthermore, as discussed above, the nP3 process can also be used to correct TTV/flatness errors in the finished waveguide by profiling an unpatterned portion of the waveguide substrate. FIG. 10 illustrates using the nP3 process on an unpatterned portion of the waveguide substrate to correct for aberrations in accordance with an embodiment of the present invention. In particular, in this case, the use of the nP3 process to correct for TTV errors is shown. The profiling material has a substantially similar refractive index as the substrate and is left behind on the substrate at a wavelength of interest. By correcting TTV and other substrate distortion errors, optical aberrations (e.g., image misalignment between the real and virtual images, shift in the image focus, etc.) and dispersion errors are minimized.

As shown in FIG. 10, a projector 1001 injects a virtual image into a waveguide 1002 in which the incoupling DOE 1003 couples light 1004 into waveguide 1002, in which waveguide 1002 includes profiling material on a substrate 1005. The real image is then transmitted through waveguide 1002.

As further shown in FIG. 10, the outcoupling DOE 1006 couples light 1007 out of waveguide 1002 in eye box 1008.

Furthermore, as shown in FIG. 10, a real image 1009 is transmitted through waveguide 1002.

In one embodiment, the principles of the present invention use a controlled, customized variation in one or more geometric parameters of the DOE to achieve desired uniformity in diffraction characteristics and/or efficiency by overcoming fabrication errors or to achieve a controlled variation in diffraction characteristics and/or efficiency. For a 1D grating, the geometric parameters could be the depth or height of a feature of the grating, a lateral width of a feature, the orientation of the grating, i.e., the angle that a line on the grating makes with respect to a given axis on the waveguide, the width of a feature, or the angle of a feature with respect to a horizontal plane. In one embodiment, the height is varied in a range between 10-400 nm. For a 2D grating with a polygonal shape, the geometric parameters that can have a controlled variation could be the depth of a feature of the grating in one or more directions, the orientation of the 2D grating with respect to a given axis on the waveguide substrate, the relative spacing between two polygons that comprise the 2D grating, or the angle that a side of the polygon makes with respect to a horizontal line. In one embodiment, the height is varied in a range between 10-400 nm. While this embodiment specifically discloses the use of a controlled, customized variation of one or more geometric parameters in diffractive optical elements for waveguide substrates, its use can be extended to the use of introducing a customized, controlled variation of one or more geometric parameters in nanoscale patterns. In one embodiment, the use of such a controlled variation is to compensate for errors in prior fabrication steps or anticipated errors in subsequent fabrication steps.

In a typical example, the diffraction gratings are fabricated using nanoimprint lithography with the help of a master template. Master templates can be fabricated using standard lithography techniques, such as e-beam lithography, photolithography, etc. The introduction of a controlled variation of one or more grating parameters in the master template itself can make the fabrication of the template prohibitively expensive using the aforementioned lithography techniques. The principles of the present invention utilize the nP3 process to introduce a controlled, programmable/customizable variation in one or more diffraction grating parameters on the master template. As an example, a controlled variation in the grating depth is discussed. For this purpose, the master template is first fabricated on silicon, fused silica or other substrate using standard lithography techniques without the desired parametric variation in depth. Subsequently, the nP3 process is used to fill the gratings with a UV-curable polymer and also to deposit a film with the desired thickness profile on top of the filled gratings. This process can be conducted in a single step, where the nP3 drop generation algorithm is modified to account for the volume of liquid used to fill the gratings in addition to that needed to create the controlled profile, where such a profile can be linear, parabolic, or any other polynomial in one or more dimensions.

Furthermore, this profile can have different orientations. For example, a part of the DOE on the waveguide may have a varying depth profile in one direction, whereas, another portion of the same DOE or a different DOE may have a varying depth profile in a different direction. Furthermore, in one embodiment, the transition from regions with different orientations of the grating depth profile can occur within 5 micrometers to 10 millimeters. In one embodiment, such a process is conducted in multiple iterations where a first iteration may be used to substantially planarize the grating features and one or more subsequent iterations may be used to obtain the desired film thickness profile in one or more different directions. In one embodiment, the film thickness above the grating structure after the planarization step is substantially uniform, where the mean film thickness can be chosen to mitigate the defects that were caused due to bubbles trapped in the polymer film. For example, individual drops merging in 1D grating structures flow preferentially in the direction parallel to the grating lines. The flow of these drops is governed by the pressure applied by the superstrate during the nP3 process. If the mean film thickness is sub-optimal, it can reduce the pressure in the film thereby causing the bubbles to persist for longer than desired. Hence, based on the nanoscale pattern geometry and a desired throughput, the mean film thickness can be chosen to keep the number of defects below a defined tolerance. This can also be obtained with the help of a model. Furthermore, this process may be used to correct undesirable variations in the depth or other geometric parameters of a fabricated waveguide substrate to match a desired specification. For example, a waveguide substrate may be fabricated and its performance measured. If the performance is not desirable, it can be subject to the nP3 process above such that the deposited film thickness profile and a subsequent plasma etch (described below) can result in the desired profile of the geometric parameter.

After obtaining the desired profile in the polymer film, the waveguide substrate is subject to a plasma etch process. In the etch process, the polymer film and the waveguide substrate are etched in a plasma chemistry that yields a substantially similar etch rate for both the polymer and the underlying substrate, where the underlying substrate can be Si, fused silica, high-index glass (e.g., Schott Realview®), etc. This allows the deposited profile to be directly transferred to the underlying substrate such that the desired parameter of the diffraction grating (such as the depth) obtains the same parametric variation that is manifest in the film thickness profile. Moreover, if the relative etch rates between the film and the substrate are modulated to have a ratio that is not equal to one, the transferred profile of the grating depth scales with the ratio of the etch depth. In one embodiment, the nP3 process and the etch process are conducted simultaneously across the regions of the nanoscale pattern on the substrate.

This tuning of the etch rate ratio can thus be an additional control knob to obtain the desired profile. The substrate can be cleaned to remove any residual resist or contamination from the etch. At the end of the process, it is desired to keep the surface roughness of the substrate substantially similar to the value before nP3, or to increase it by no more than 1 nm. In one embodiment, the average surface roughness of the nanoscale pattern with the customized variations is substantially equivalent to the average surface roughness of the nanoscale pattern without the customized variation.

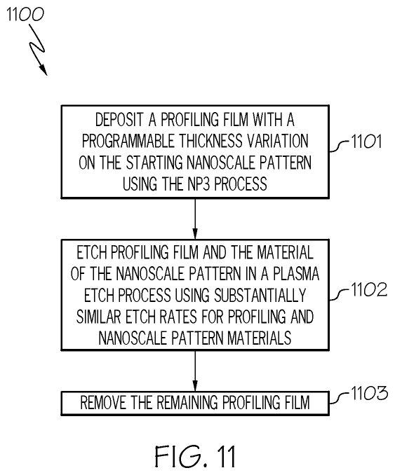

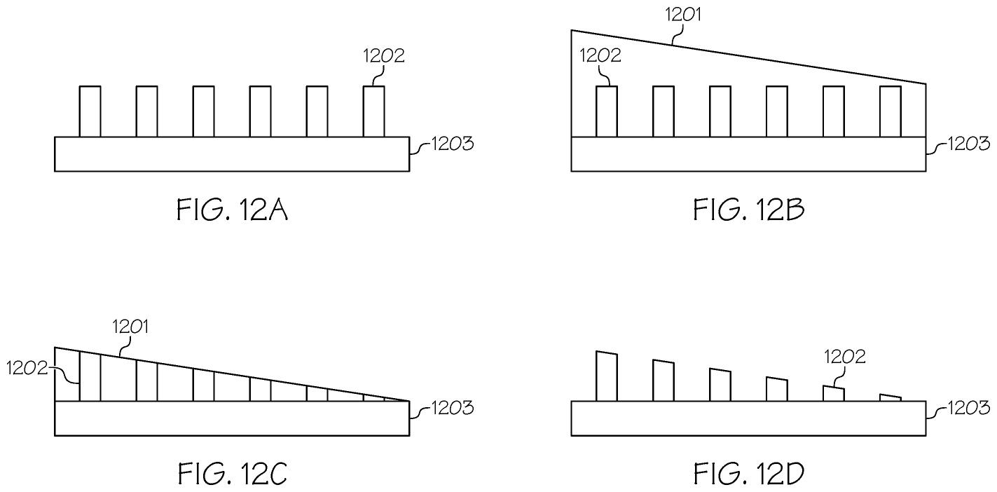

Referring to FIG. 11, FIG. 11 illustrates a method 1100 for introducing a customized variation in a geometric parameter (e.g., height) of a nanoscale pattern using substantially similar etch rates for the profiling and nanoscale pattern materials in accordance with an embodiment of the present invention. FIGS. 12A-12D depict cross-sectional views for introducing a customized variation in a geometric parameter (e.g., height) of a nanoscale pattern using the steps described in FIG. 11 in accordance with an embodiment of the present invention.

As will be discussed in further detail below, FIGS. 11 and 12A-12D illustrate utilizing the nP3 process with the plasma etch process on an exemplar grating structure in order to introduce a customized variation in a geometric parameter (e.g., height) of a nanoscale pattern.

Referring now to FIG. 11, in conjunction with FIGS. 12A-12D, in step 1101, a profiling film 1201 with a programmable thickness variation is deposited on the starting nanoscale pattern 1202 on the substrate 1203 (exemplar grating structure) using the nP3 process as shown in FIGS. 12A-12B.

In step 1102, profiling film 1201 and the material of the nanoscale pattern 1202 are etched in a plasma etch process using substantially similar etch rates for the profiling and nanoscale pattern materials as shown in FIG. 12C.

In step 1103, the remaining profiling film 1201 is removed using either a wet process (e.g., Piranha clean) or a dry process (e.g., UV ozone cleaning, O₂ ashing, etc.) forming a structure as shown in FIG. 12D.

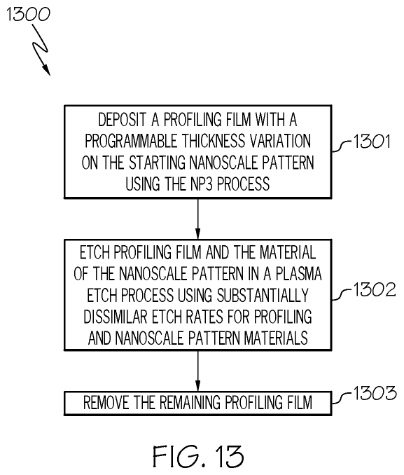

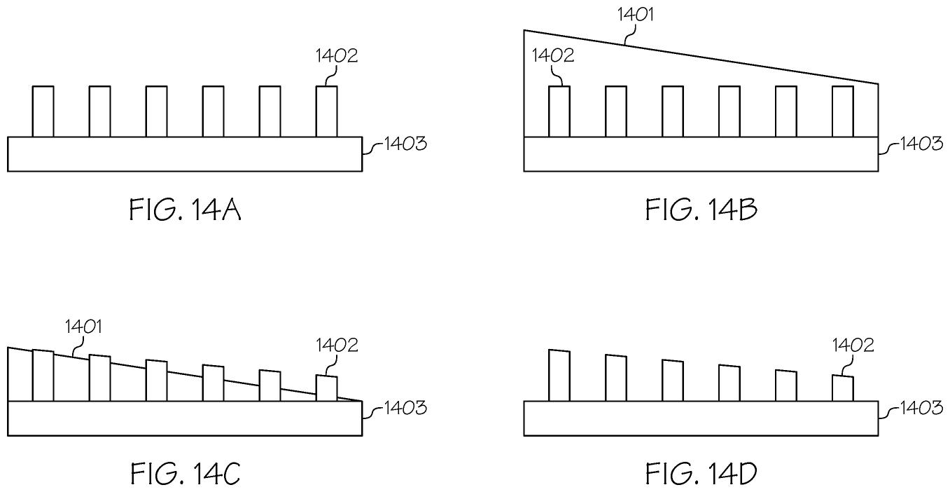

As illustrated in FIGS. 12C-12C, profiling film 1201 and the material of the nanoscale pattern 1202 are etched in a plasma etch process with similar etch rates. An illustration of introducing a customized variation in a geometric parameter (e.g., height) of a nanoscale pattern in which the etch rates for the profiling and nanoscale pattern materials are substantially dissimilar is discussed below in connection with FIGS. 13 and 14A-14D.

Referring to FIG. 13, FIG. 13 illustrates a method 1300 for introducing a customized variation in a geometric parameter (e.g., height) of a nanoscale pattern using substantially dissimilar etch rates for the profiling and nanoscale pattern materials in accordance with an embodiment of the present invention. FIGS. 14A-14D depict cross-sectional views for introducing a customized variation in a geometric parameter (e.g., height) of a nanoscale pattern using the steps described in FIG. 13 in accordance with an embodiment of the present invention.

Referring now to FIG. 13, in conjunction with FIGS. 14A-14D, in step 1301, a profiling film 1401 with a programmable thickness variation is deposited on the starting nanoscale pattern 1402 on the substrate 1403 (exemplar grating structure) using the nP3 process as shown in FIGS. 14A-14B.

In step 1302, profiling film 1401 and the material of the nanoscale pattern 1402 are etched in a plasma etch process using substantially dissimilar etch rates for the profiling and nanoscale pattern materials as shown in FIG. 14C.

In step 1303, the remaining profiling film 1401 is removed using either a wet process (e.g., Piranha clean) or a dry process (e.g., UV ozone cleaning, O₂ ashing, etc.) forming a structure as shown in FIG. 14D.

As a result of using the principles of the present invention discussed above, the processing accuracy in fabricating optical elements is improved.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for introducing a customized variation of a geometric parameter in a nanoscale pattern on a substrate, the method comprising:
conducting a nanoscale precision programmable profiling process on one or more regions of said substrate with said nanoscale pattern, wherein said nanoscale precision programmable profiling process is used to deposit a profiling film with a thickness profile that is a function of said customized variation of said geometric parameter in said nanoscale pattern; and
conducting a plasma etch process of said profiling film and material of said nanoscale pattern that converts said thickness profile of said profiling film into said customized variation of said geometric parameter in said nanoscale pattern, wherein said customized variation is a function of said thickness profile of said profiling film.

2. The method as recited in claim 1, wherein said nanoscale pattern is one or more of the following: a 1D diffraction grating, a 2D diffraction grating, a multilevel grating, a slanted grating, a surface relief gratings, a Bragg grating, a volume hologram, and a photonic crystal.

3. The method as recited in claim 1, wherein said substrate is a high-index waveguide substrate, wherein said method is executed on a patterned side of said high-index waveguide substrate, and wherein said nanoscale pattern comprises a diffractive optical element.

4. The method as recited in claim 1, wherein said geometric parameter comprises one or more of the following: a depth or a height of a feature, a lateral width of a feature, and an angle of one dimension with respect to a horizontal plane.

5. The method as recited in claim 1, wherein one or more properties of said customized variation is different for different regions of said nanoscale pattern on said substrate.

6. The method as recited in claim 1, wherein said conducting of said nanoscale precision programmable profiling process and said conducting of said plasma etch process are carried out simultaneously across a plurality of regions of said nanoscale pattern on said substrate.

7. The method as recited in claim 1, wherein said customized variation is achieved in multiple iterations of said conducting of said nanoscale precision programmable profiling process and said conducting of said plasma etch process.

8. The method as recited in claim 1, wherein an average surface roughness of said nanoscale pattern with said customized variation is substantially equivalent to an average surface roughness of said nanoscale pattern without said customized variation.

9. The method as recited in claim 1, wherein a ratio of etch rates of said profiling film and said nanoscale pattern material is substantially matched.

10. The method as recited in claim 1, wherein a ratio of etch rates of said profiling film and said nanoscale pattern material is tunable between 0.05 and 20.

11. The method as recited in claim 1, wherein a customized spatial variation is accomplished in said profiling film using one or more of the following: an inkjet, differential heating with a superstrate, and differential heating without a superstrate.

12. The method as recited in claim 1, wherein said profiling film has an optical property that is substantially matched with said nanoscale pattern.

13. A method for correcting one or more aberrations in a waveguide substrate, the method comprising:
performing a nanoscale precision programmable profiling process on an unpatterned portion of said waveguide substrate by depositing a profiling film on said unpatterned portion of said waveguide substrate with a customized variation to correct for said one or more aberrations in said waveguide substrate.

14. The method as recited in claim 13 further comprising:
performing a plasma etch of said profiling film to transfer a desired profile to an underlying material of said profiling film.

15. The method as recited in claim 13, wherein said unpatterned portion of said waveguide substrate lies on a surface of said waveguide substrate that does not contain diffractive optical elements.

16. The method as recited in claim 13, wherein said unpatterned portion of said waveguide substrate has a nanoscale texture.

17. The method as recited in claim 13, wherein said one or more aberrations result from one or more of the following: substrate total thickness variation (TTV) errors and deposition of films.

18. An apparatus for introducing a customized variation of a geometric parameter in a nanoscale pattern on a substrate, the apparatus comprising:
a profiling module, wherein said profiling module has an inkjet for depositing a profiling film on a substrate with a thickness profile that is a function of said customized variation of said geometric parameter in said nanoscale pattern on said substrate, wherein a plasma etch process is conducted on said profiling film and material of said nanoscale pattern that converts said thickness profile of said profiling film into said customized variation of said geometric parameter in said nanoscale pattern on said substrate, wherein said customized variation is a function of said thickness profile of said profiling film.

19. The apparatus as recited in claim 18, wherein said substrate comprises a waveguide substrate, wherein said substrate has a region with an optical element with said customized variation of said geometric parameter in said nanoscale pattern on said substrate.

20. An XR device, the device comprising:
a waveguide that is fabricated using nanoscale precision programmable profiling for one or more of the following: introducing a customized variation in a geometric parameter of a nanoscale pattern on said waveguide, correction of substrate flatness or total thickness variation errors, and correction of image distortions or optical aberrations.
